(19) United States
(12) Patent Application Publication
(10) Pub. No.: US 2007/0267172 A1
(43) Pub. Date: Nov. 22, 2007

(54) HEAT DISSIPATION APPARATUS

(75) Inventors: CHING-BAI HWANG, TU CHENG (TW); JIN-GONG MENG, SHENZHEN (CN)

Correspondence Address: PCE INDUSTRY, INC.;ATT. CHENG-JU CHIANG JEFFREY T. KNAPP, 458 E. LAMBERT ROAD, FULLERTON, CA, 92835, US

(73) Assignee: FOXCONN TECHNOLOGY CO., LTD., Tu-Cheng (TW)

(21) Appl. No.: 11/308,865

(22) Filed: May 16, 2006

(51) Int. Cl. H05K 7/20

(52) U.S. Cl. 165/80.3; 165/104.33; 361/700; 257/715

(57) ABSTRACT

A heat dissipation apparatus (10) for dissipating heat from a heat-generating electronic component includes a fin assembly (12) and a centrifugal blower (14). The fin assembly includes a plurality of fins (121) for thermally connecting with the heat-generating electronic component to absorb heat therefrom. The centrifugal blower provides an airflow flowing through the fin assembly to take heat away therefrom. The centrifugal blower includes a housing (141), a cover (142) mounted on the housing with an inner space formed therebetween, and a rotor including a plurality of blades (143) rotatably disposed in the inner space. The rotor has a rotation axis (A). The fins of the fin assembly are arranged at an air outlet (151) of the centrifugal blower and stacked together along a direction parallel to the rotation axis of the rotor of the centrifugal blower.

### FIELD OF THE INVENTION

The present invention relates generally to a heat dissipation apparatus, and more particularly to a heat dissipation apparatus for dissipating heat generated by electronic components, wherein the apparatus has a fin assembly including a plurality of fins stacked together along a direction parallel to a rotation axis of a centrifugal blower, for making an airflow generated by the centrifugal blower to flow more smoothly and evenly through the fin assembly.

### DESCRIPTION OF RELATED ART

Following the increase in computer processing power that has been seen in recent years, greater emphasis is now being laid on increasing the efficiency and effectiveness of heat dissipation devices. Referring to FIG. 7, a conventional heat dissipation apparatus 20 includes a centrifugal blower 22 and a fin assembly 24 disposed at an air outlet 211 of the centrifugal blower 22. The fin assembly 24 includes a plurality of fins 242 which thermally connect with a heat generating electronic component (not shown) to absorb heat therefrom. The centrifugal blower 22 includes a casing 222, a stator (not shown) mounted in the casing 222, and a rotor 223 rotatably disposed around the stator. When the centrifugal blower 22 is activated, the rotor 223 rotates along a counterclockwise direction around the stator to drive an airflow to flow through the fin assembly 24 to take away heat therefrom.

In operation of the heat dissipation apparatus 20, the casing 222 guides the airflow to move toward an upper side 246 of the air outlet 211 of the centrifugal blower 22. A portion of the airflow leaves the centrifugal blower 22 at the upper side 246 of the air outlet 211 with another portion flowing toward a bottom side 244 of the fin assembly 24 from the upper side 246 thereof. A flow direction of the airflow flowing toward the upper side 246 of the fin assembly 24 is substantially parallel to the fins 242 thereof, while the airflow flowing toward the bottom side 244 of the fin assembly 24 forms an acute angle with each fin 242 of the bottom side 244 of the fin assembly 24. The airflow flowing toward the bottom side 244 of the fin assembly 24 may be deflected by the fins 242 thereof due to the acute angles formed therebetween. This deflection of the airflow may cause a loss in kinetic energy of the airflow. Thus, speed of the airflow flowing toward the bottom side 244 of the fin assembly 24 may be reduced. The heat dissipation efficiency of the heat dissipation apparatus 20 will thereby be further reduced. Accordingly, it can be seen that the heat dissipation efficiency of the heat dissipation apparatus 20 has room for improvement.

### SUMMARY OF THE INVENTION

The present invention relates to a heat dissipation apparatus for dissipating heat from a heat-generating electronic component. According to a preferred embodiment of the present invention, the heat dissipation apparatus has a fin assembly and a centrifugal blower. The fin assembly includes a plurality of fins for thermally connecting with the heat-generating electronic component to absorb heat therefrom. The centrifugal blower provides an airflow flowing through the fin assembly to take heat away therefrom. The centrifugal blower includes a housing, a cover mounted on the housing with an inner space formed therebetween, a stator accommodated in the inner space, and a rotor including a plurality of blades rotatably disposed around the stator and having a rotation axis. The fins of the fin assembly are arranged at an air outlet of the centrifugal blower and stacked together along a direction parallel to the rotation axis of the rotor of the centrifugal blower.

Other advantages and novel features of the present invention will become more apparent from the following detailed description of preferred embodiment when taken in conjunction with the accompanying drawings, in which:

### BRIEF DESCRIPTION OF THE DRAWINGS

FIG. 1 is an exploded, isometric view of a heat dissipation apparatus according to a preferred embodiment of the present invention;

FIG. 2 is a partly assembled view of the heat dissipation apparatus of FIG. 1;

FIG. 3 is an assembled view of the heat dissipation apparatus of FIG. 1;

FIG. 4 is an assembled view of the heat dissipation apparatus of FIG. 1, but viewed from another aspect;

FIG. 5 is a partly assembled view of a heat dissipation apparatus according to a second embodiment of the present invention;

FIG. 6 is a partly assembled view of a heat dissipation apparatus according to a third embodiment of the present invention; and

FIG. 7 is a top view of a conventional heat dissipation apparatus with some parts thereof removed.

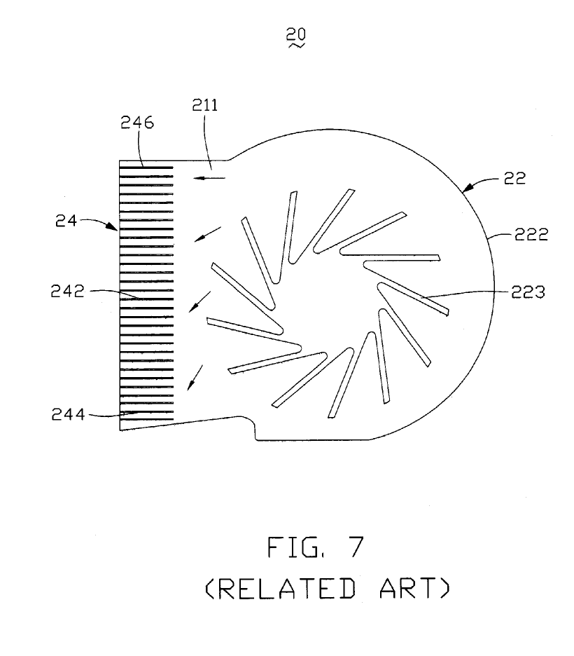

### DETAILED DESCRIPTION OF THE INVENTION

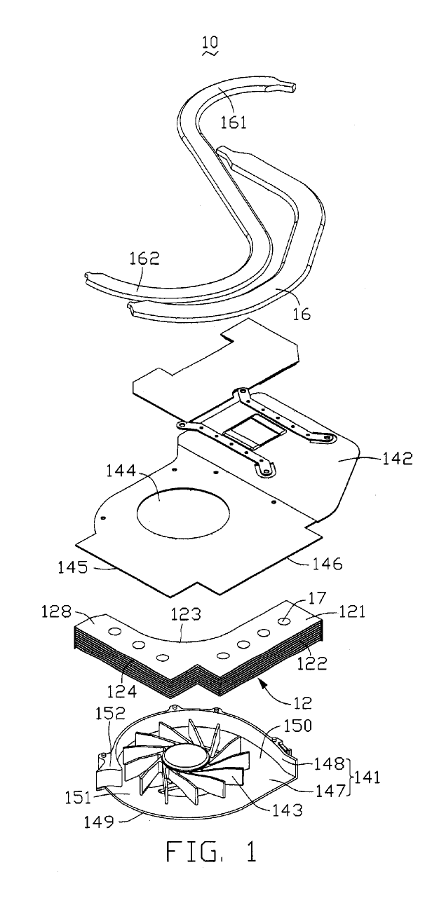

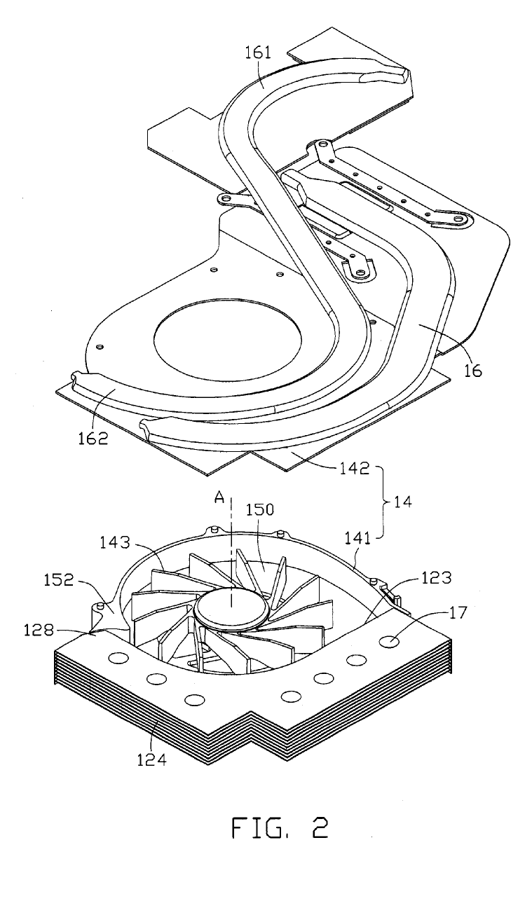

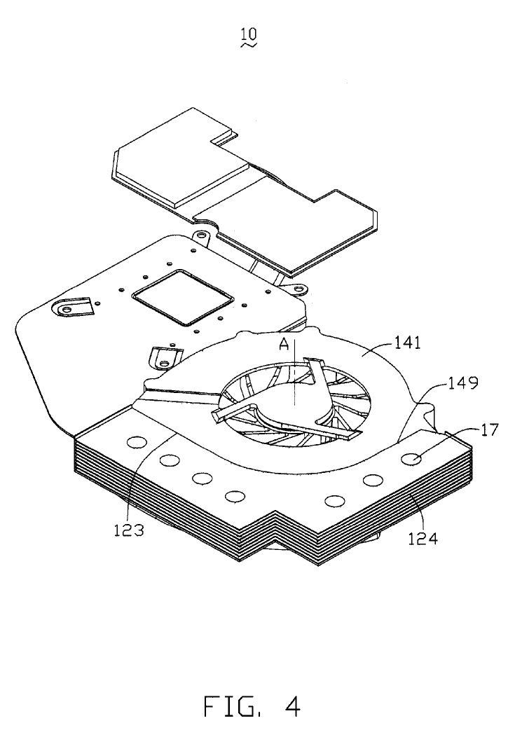

Referring to FIGS. 1 through 4, a heat dissipation apparatus 10 according to a preferred embodiment of the present invention is shown. The heat dissipation apparatus 10 includes a fin assembly 12 and a centrifugal blower 14 (shown in FIG. 2). The fin assembly 12 includes a plurality of stacked fins 121 thermally connecting with two heat generating electronic components (not shown) to absorb heat therefrom. The centrifugal blower 14 enables to provide an airflow with a high air pressure so as to take away heat from the fin assembly 12.

The heat-generating electronic components are disposed at a lateral side of the fin assembly 12. The fin assembly 12 connects with the heat-generating electronic components via an arc-shaped heat pipe 16 and a serpentine heat pipe 16. Each of the heat pipes 16 has an evaporator section 161 contacting with a corresponding heat-generating electronic component, and a condenser section 1 62 thermally contacting with the topmost fin 121 of the fin assembly 12. A plurality of heat transfer members 17, such as U-shaped heat pipes, metallic posts, or metallic plates, extending through the fin assembly 12, for transferring heat from the topmost fin 121 to the other fins 121 of the fin assembly 12. Alternatively, the fin assembly may connect with the heat-generating electronic components via a plurality of flexible heat pipes, each of which has an evaporator section contacting with the corresponding heat-generating electronic component, and a condenser section extending through the fins of the fin assembly. The fin assembly may also be directly arranged on the heat-generating electronic components to absorb heat thereform.

The centrifugal blower 14 includes a housing 141, a cover 142 attached to the housing 141 with an inner space formed therebetween, a stator (not shown) accommodated in the inner space, and a rotor (not labeled) including a plurality of blades 143 rotatably disposed around the stator. The cover 142 defines a through hole therein functioning as an air inlet 144 of the centrifugal blower 14, and two linear edges 145,146 perpendicular to each other. The housing 141 includes a flat bottom wall 147 perpendicular to the rotation axis A of the rotor, and a sidewall 148 perpendicular to the bottom wall 147. The bottom wall 147 includes an arcuate edge 149 corresponding to the linear edges 145, 146 of the cover 142. An air channel 150 is formed between the blades 143 and an inner surface of the sidewall 148. The sidewall 148 of the housing 141 defines an opening therein functioning as an air outlet 151 of the centrifugal blower 14, and protrudes a tongue 152 adjacent to the linear edge 145 of the cover 142. A distance between the inner surface of the sidewall 148 and the free ends of the blades 143 is gradually reduced from an end of the side wall 148 remote from the tongue 152 toward the tongue 152; such design increases the pressure of the airflow when it leaves the air channel 150 into the air outlet 151 via the tongue 152. However a flowing direction of the airflow is deflected away from the tongue 152. The amount of air arriving at the fins 121 adjacent to the tongue 152 is reduced, which decreases the heat dissipating efficiency of that fins 121 of the fin assembly 12. In order to solve this problem, the fin assembly 12 needs to be located close to the tongue 152 of the centrifugal blower 14, whereby the airflow can immediately arrive at that fins 121 once it leaves the air channel 150.

Each fin 121 of the fin assembly 12 is disposed along a lateral direction of the air outlet 151 of the centrifugal blower 14, with the topmost fin 121 intimately contacting with a flat bottom surface of the cover 142 and a bottom surface of the fin assembly 12 coplanar with a bottom surface of the bottom wall 147 of the housing 141. Each of the fins 121 spreads at the entire air outlet 151 of the centrifugal blower 14. The fins 121 are stacked together along a direction substantially parallel to the rotation axis A of the rotor. A plurality of air passages 122 are formed between two adjacent fins 121 and perpendicular to the rotation axis A of the rotor. Each of the fins 121 includes an arcuate inner fringe 123 mated with the arcuate edge 149 of the housing 141, and two linear outer fringes 124 aligning with the linear edges 145, 146 of the cover 142 respectively. The arcuate fringes 123 of the fins 121 are disposed nearer to the blades 143 of the centrifugal blower 14 than the fins of the conventional heat dissipation apparatus. The kinetic energy of the airflow flowing through the fins 121 is thus increased, which increases the heat dissipating efficiency of the fin assembly 12. Each of the fins 121 further includes a tongue portion 128 extending to the tongue 152 of the centrifugal blower 14, to increase the heat dissipating efficiency of the fins 121 adjacent to the tongue 152.

In the present invention, the air passages 122 of the fin assembly 12 are perpendicular to the rotation axis A of the rotor. Thus, a flow direction of the airflow is substantially parallel to the air passages 122 of the fin assembly 12. The airflow is thereby smoothly and evenly flowing through the fin assembly 12, which prevents the kinetic energy of the airflow from reducing. The heat dissipating efficiency of the heat dissipation apparatus 10 is therefore increased. The tongue portion 128 of fin assembly 12 extends adjacent to the tongue 152 of the centrifugal blower 14, which increases the heat dissipating efficiency of the fins 121 adjacent to the tongue 152 since the airflow can immediate flow to the fins 121 once the airflow leaves the air channel 150. The heat dissipating efficiency of the heat dissipation apparatus 10 is further increased.

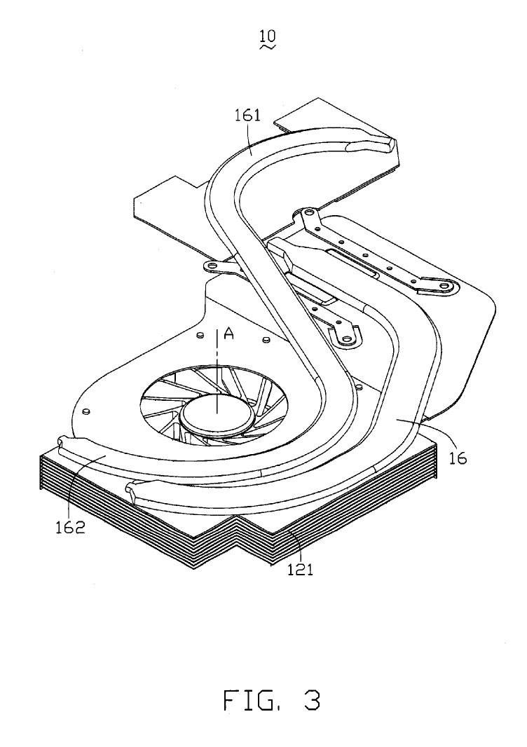

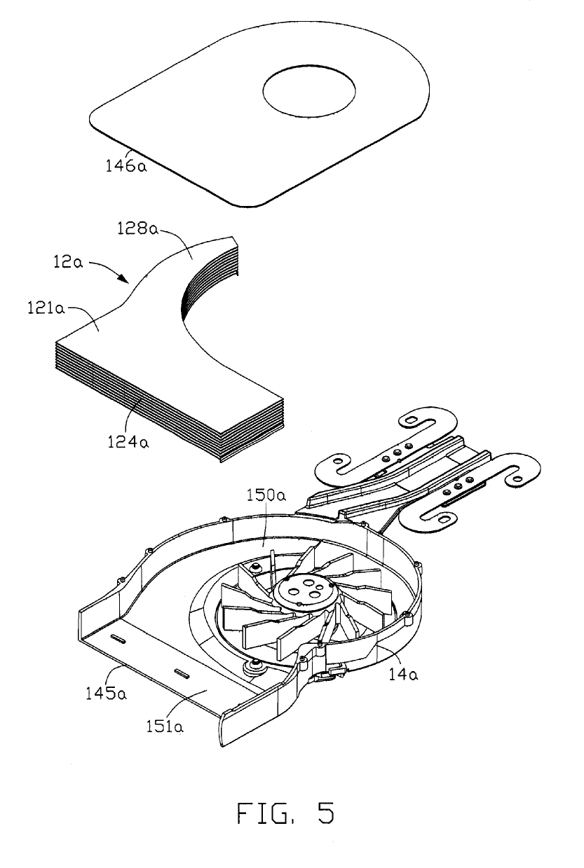

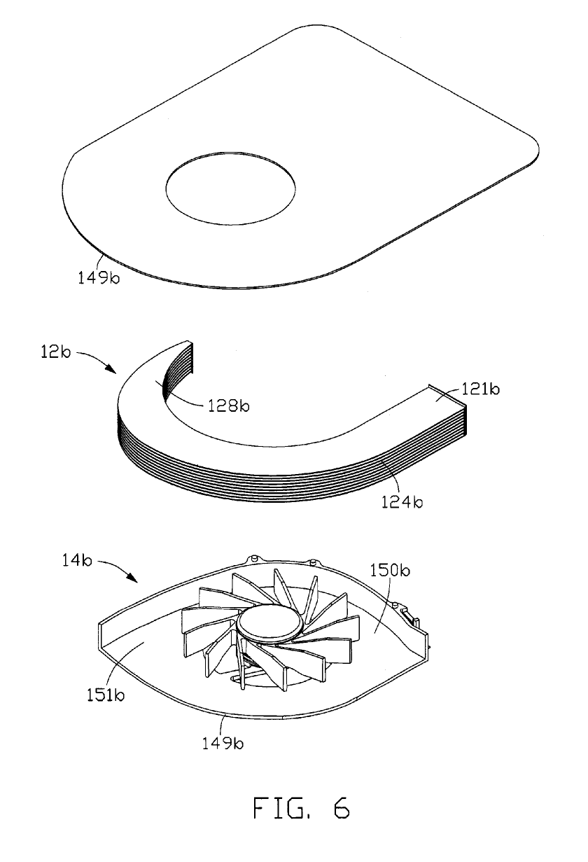

In the present invention, the fins 121 of the fin assembly 12 can be designed to satisfy a larger contacting area with the heat pipes 16 (shown in FIG. 3). In addition, the fins of the fin assembly can also be designed to have other shapes to mate with air outlets of centrifugal blowers having other configurations other than the previous first embodiment. Referring to FIGS. 5 and 6, second and third embodiments of the present invention are shown. In the second embodiment, the centrifugal blower 14a has two parallel linear edges 145a, 146a at two sides of the air outlet 151a. Each fin 121a of the fin assembly 12a includes a linear outer fringe 124a corresponding to the linear edges 145a, 146a of air outlet 151a of the centrifugal blower 14a, and an arcuate tongue portion 128a extending into the air channel 150a of the centrifugal blower 14a to increase the heat dissipating efficiency between the fins 121 and the airflow. In the third embodiment, the centrifugal blower 14b has two parallel acuate edges 149b at two sides of air outlet 151b. Each fin 121b of the fin assembly 12b is designed to have an arcuate outer fringe 124b corresponding to the acuate edges 149b of the air outlet 151b of the centrifugal blower 14b, and an arcuate tongue portion 128b extending into the air channel 150b of the centrifugal blower 14.

It is to be understood, however, that even though numerous characteristics and advantages of the present invention have been set forth in the foregoing description, together with details of the structure and function of the invention, the disclosure is illustrative only, and changes may be made in detail, especially in matters of shape, size, and arrangement of parts within the principles of the invention to the full extent indicated by the broad general meaning of the terms in which the appended claims are expressed.

What is claimed is:

1. A heat dissipation apparatus configured for dissipating heat from at least a heat-generating electronic component comprising:
a fin assembly comprising a plurality of fins configured for thermally connecting with the at least a heat-generating electronic component to absorb heat therefrom; and
a centrifugal blower for providing an airflow flowing through the fin assembly to take heat away therefrom, the centrifugal blower comprising a housing, a cover mounted on the housing with an inner space formed therebetween, a rotor including a plurality of blades rotatably disposed in the housing;
wherein the fins of the fin assembly are arranged at an air outlet of the centrifugal blower and stacked together along a direction parallel to a rotation axis of the rotor of the centrifugal blower.

2. The heat dissipation apparatus as described in claim 1, wherein the cover comprises two non-parallel linear edges at the air outlet, each fin of the fin assembly comprises two non-parallel linear outer fringes corresponding to the linear edges of the cover.

3. The heat dissipation apparatus as described in claim 2, wherein the housing comprises an arcuate edge at the air outlet, each fin of the fin assembly comprises an arcuate inner fringe mated with the arcuate edge of the housing.

4. The heat dissipation apparatus as described in claim 1, wherein the housing and the cover comprise two parallel linear edges at the air outlet, each fin of the fin assembly has a linear outer fringe corresponding to the linear edges at the air outlet of the centrifugal blower.

5. The heat dissipation apparatus as described in claim 1, wherein the housing and the cover comprise two parallel acuate edges at the air outlet, each fin of the fin assembly has an arcuate outer fringe corresponding to the acuate edges at the air outlet of the centrifugal blower.

6. The heat dissipation apparatus as described in claim 1, wherein a bottom surface of the fin assembly is coplanar with a bottom surface of the housing as the fin assembly is mounted to the centrifugal blower.

7. The heat dissipation apparatus as described in claim 1, wherein each fin of the fin assembly comprises a tongue portion extending to a tongue of the centrifugal blower, the tongue of the centrifugal blower is located at a lateral side of the air outlet.

8. The heat dissipation apparatus as described in claim 1, further comprising a heat pipe having an evaporator section configured for contacting with the at least a heat-generating electronic component, and a condenser section contacting with a topmost fin of the fin assembly.

9. The heat dissipation apparatus as described in claim 8, further comprising at least a heat transfer member extending through the fin assembly, for transferring heat from the topmost fin to the other fins of the fin assembly.

10. An electronic apparatus comprising:
an electronic component;
a centrifugal blower disposed at one side of the electronic component and comprising a rotor with blades rotatable around a rotational axis of the rotor, and defining at least an air outlet through which an airflow generated by the blades flows; and
a fin assembly comprising a plurality of fins with each of the fins spreading along a lateral direction of the air outlet and absorbing heat from the electronic component, the fins being stacked together along a direction non-perpendicular to the rotational axis of the rotor of the centrifugal blower.

11. The electronic apparatus as described in claim 10, further comprising a heat pipe connected the electronic component with the fin assembly.

12. The electronic apparatus as described in claim 10, wherein each fin of the fin assembly comprises a tongue portion disposed adjacent to a tongue of the centrifugal blower, the tongue of the centrifugal blower is located at a lateral side of the air outlet.

13. The electronic apparatus as described in claim 10, wherein each fin of the fin assembly comprises a tongue portion, the tongue portion extending into an air channel formed between blades of the rotor and a housing of the centrifugal blower.

14. The electronic apparatus as described in claim 10, wherein the centrifugal blower comprises two linear edges and an arcuate edge respectively disposed at two sides of the air outlet, each fin of the fin assembly comprises two linear outer fringes corresponding to the linear edges of the centrifugal blower, and an arcuate inner fringe mated with the arcuate edge thereof.

15. The electronic apparatus as described in claim 10, wherein the centrifugal blower comprises two linear edges at two sides of the air outlet, each fin of the fin assembly has a linear outer fringe corresponding to the linear edges.

16. The electronic apparatus as described in claim 10, wherein the centrifugal blower comprises acuate edges at two sides of the air outlet, each fin of the fin assembly has an arcuate fringe corresponding to the acuate edges.

17. The electronic apparatus as described in claim 10, wherein the fins are stacked together along a direction parallel to the rotation axis of the rotor.

18. A heat dissipation apparatus comprising:
a centrifugal blower having a rotor with blades rotatable about a rotation axis thereof and an outlet through which an airflow generated by the rotor flows;
a fin assembly mounted on the outlet of the centrifugal blower, the fin assembly having a plurality of fins stacked together along a direction parallel to the rotation axis of the rotor; and
a heat pipe having a condenser portion thermally connecting with the fin assembly and an evaporator portion adapted for thermally connecting with a heat-generating electronic component.

19. The heat dissipation apparatus of claim 18, wherein the blower has an air channel between the blades and a wall of the blower, the airflow flows from the air channel to the air outlet, the fin assembly forms a tongue portion extending to a portion of the air outlet close to the air channel.

20. The heat dissipation apparatus of claim 18, wherein the blower has an air channel between the blades and a wall of the blower, the airflow flows from the air channel to the air outlet, the fin assembly forms a tongue portion extending into the air channel.
